(19) United States
(12) Patent Application Publication
(10) Pub. No.: US 2024/0333227 A1
(43) Pub. Date: Oct. 3, 2024

(54) DOHERTY AMPLIFIER

(71) Applicant: Murata Manufacturing Co., Ltd., Kyoto (JP)

(72) Inventor: Shohei IMAI, Kyoto (JP)

(21) Appl. No.: 18/619,797

(22) Filed: Mar. 28, 2024

(30) Foreign Application Priority Data
Mar. 31, 2023 (JP) 2023-058639

(51) Int. Cl. H03F 1/02

(52) U.S. Cl. CPC H03F 1/0288; H03F 2200/451; H03F 2200/474

(57) ABSTRACT

A Doherty amplifier includes a carrier amplifier amplifying a radio frequency signal, a peak amplifier amplifying a radio frequency signal and including a driver stage peak amplifier and a power stage peak amplifier receiving an output of the driver stage peak amplifier, a drive level detection circuit detecting a drive level of the carrier amplifier, a control circuit outputting a signal to set a bias of the driver stage peak amplifier based on a drive level signal indicating the drive level detected by the drive level detection circuit, and a generation circuit generating a current or a voltage in accordance with an operating state of the driver stage peak amplifier. An operating state of the power stage peak amplifier is controlled based on the current or the voltage generated by the generation circuit in accordance with the operating state of the driver stage peak amplifier.

### CROSS REFERENCE TO RELATED APPLICATION

This application claims priority from Japanese Patent Application No. 2023-058639 filed on Mar. 31, 2023. The content of this application is incorporated herein by reference in its entirety.

### BACKGROUND ART

The present disclosure relates to a Doherty amplifier.

A Doherty amplifier is known as a highly efficient power amplifier. The Doherty amplifier has, in general, a configuration in which a carrier amplifier and a peak amplifier are coupled in parallel. The carrier amplifier operates regardless of the power level of an input signal. The peak amplifier turns off when the power level of the input signal is low and turns on when the power level of the input signal is high. In the configuration above, when the power level of a radio frequency input signal is high, the carrier amplifier operates while maintaining saturation at a saturation output power level. As a result, the Doherty amplifier may increase efficiency as compared with an ordinary power amplifier.

Techniques for controlling a bias of a peak amplifier are described in U.S. Patent Application Publication No. 2016/0241209, U.S. Patent Application Publication No. 2020/0028472, and Japanese Unexamined Patent Application Publication No. 2019-41277.

With the technique described in U.S. Patent Application Publication No. 2016/0241209, saturation of a carrier amplifier is detected via a bias circuit of the carrier amplifier and a bias circuit of a peak amplifier is controlled in accordance with a detection signal.

With the technique described in U.S. Patent Application Publication No. 2020/0028472, saturation of a carrier amplifier is detected by an output signal of the carrier amplifier and a bias circuit of a peak amplifier is controlled in accordance with a detection signal.

With the technique described in Japanese Unexamined Patent Application Publication No. 2019-41277, a bias circuit of a peak amplifier is controlled in accordance with a level of a radio frequency input signal inputted to a Doherty amplifier or a level of a radio frequency input signal inputted to a carrier amplifier.

### BRIEF SUMMARY

In the techniques described in U.S. Patent Application Publication No. 2016/0241209 and U.S. Patent Application Publication No. 2020/0028472, the response time for a circuit to detect saturation of a carrier amplifier is approximately several tens of nano seconds. Therefore, the following inconvenience may occur. For example, when a radio frequency input signal having an instantaneous (much shorter than several tens of nano seconds) increase in power is inputted to a Doherty amplifier, a carrier amplifier may saturate during several tens of nano seconds from the start of saturation of the carrier amplifier to the change of the bias point of a peak amplifier. As a result, it may be difficult to maintain high quality of a radio frequency output signal of a Doherty amplifier. Further, when a Doherty amplifier is applied to a communication device, it may be difficult to maintain high communication quality.

With the technique described in Japanese Unexamined Patent Application Publication No. 2019-41277, a Doherty amplifier operates in accordance with the level of a radio frequency input signal, and the level of the radio frequency input signal is detected by a bias circuit. Accordingly, basically, the response speed is considered to be low, and thus it may be difficult to maintain the high quality of a radio frequency output signal of the Doherty amplifier.

The present disclosure suppresses deterioration in quality of a radio frequency output signal of a Doherty amplifier.

A Doherty amplifier according to an aspect of the present disclosure includes a carrier amplifier configured to amplify a radio frequency signal, a peak amplifier configured to amplify a radio frequency signal, a drive level detection circuit configured to detect a drive level of the carrier amplifier, and a control circuit configured to output a signal to set a bias of the peak amplifier based on a drive level signal indicating the drive level detected by the drive level detection circuit.

According to the present disclosure, deterioration in quality of a radio frequency output signal may be suppressed.

### BRIEF DESCRIPTION OF THE DRAWINGS

FIG. 1 is a diagram illustrating a configuration of a Doherty amplifier according to a first embodiment;

FIG. 2 is a diagram illustrating an example of a configuration of a drive level detection circuit in FIG. 1;

FIG. 3 is a diagram illustrating a specific example of the configuration of the drive level detection circuit in FIG. 1;

FIG. 4 is a diagram for describing the operation of the control circuit in FIG. 1;

FIG. 5 is a diagram illustrating a configuration of a peak amplifier included in the Doherty amplifier in FIG. 1;

FIG. 6 is a diagram illustrating a configuration example of a detection circuit;

FIG. 7 is a diagram illustrating a configuration of a Doherty amplifier according to a second embodiment; and

FIG. 8 is a diagram illustrating an example of a configuration of a current monitor circuit, a bias circuit, and the like in FIG. 7.

### DETAILED DESCRIPTION

Hereinafter, embodiments of the present disclosure will be described in detail with reference to the drawings. In the following description of each embodiment, elements the same as or equivalent to those in other embodiments are denoted by the same reference signs, and the description thereof will be simplified or omitted. The present disclosure is not limited to each of the embodiments. The constituent elements of each embodiment include elements that can be easily replaceable by those skilled in the art or are substantially the same. The configurations described below can be combined, as appropriate. The configuration may be omitted, replaced, or changed without departing from the scope of the disclosure. In the second and subsequent embodiments, the description of matters common to the first embodiment will be omitted, as appropriate, and different points will be described. In particular, similar effects of similar configurations will not be described in each embodiment.

### First Embodiment

### Overall Configuration

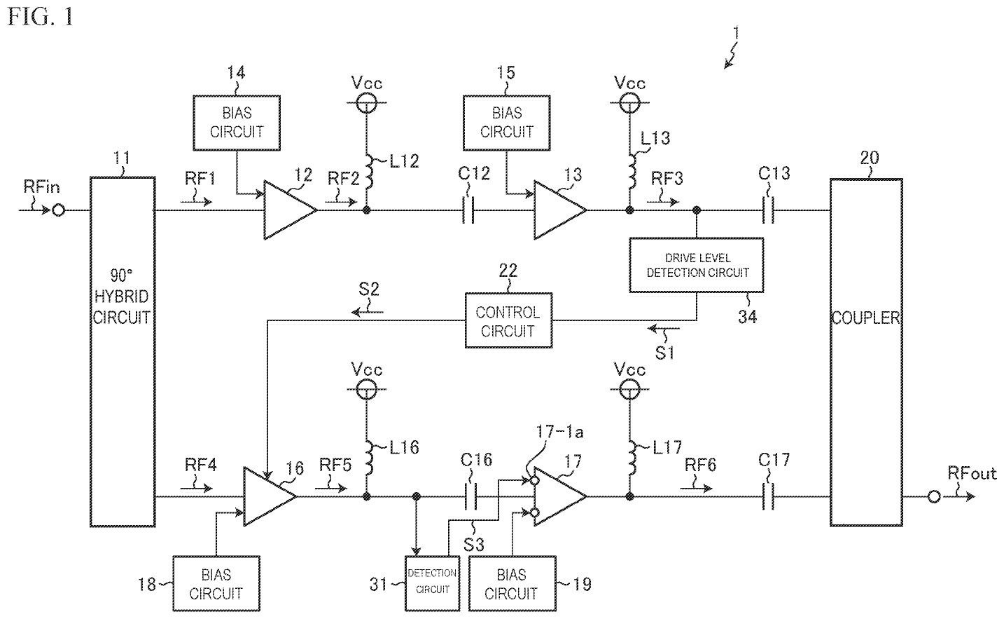

FIG. 1 is a diagram illustrating a configuration of a Doherty amplifier according to a first embodiment. In FIG. 1, the Doherty amplifier 1 of the first embodiment includes a 90° hybrid circuit 11, a first stage (driver stage) carrier amplifier 12, a final stage (power stage) carrier amplifier 13, bias circuits 14 and 15, a first stage peak amplifier 16, a final stage peak amplifier 17, a coupler 20, a drive level detection circuit 34, a control circuit 22, and a detection circuit 31.

In the Doherty amplifier 1, the 90° hybrid circuit 11 divides a radio frequency signal RFin into radio frequency signals RF1 and RF4 having phases different from each other by substantially 90°, outputs the radio frequency signal RF1 to the carrier amplifier 12, and outputs the radio frequency signal RF4 to the peak amplifier 16. The term “substantially 90°” includes not only a phase of 90° but also a phase of 90°+45°.

The radio frequency signal RF4 is exemplified to be delayed in phase by 90° from the radio frequency signal RF1. The power of the radio frequency signal RF1 and the power of the radio frequency signal RF4 are exemplified to be the same.

The bias circuit 14 applies a bias to the carrier amplifier 12. The bias circuit 15 applies a bias to the carrier amplifier 13. The carrier amplifier 12 outputs a radio frequency signal RF2 obtained by amplifying the radio frequency signal RF1 to the carrier amplifier 13. The carrier amplifier 13 outputs a radio frequency signal RF3 obtained by amplifying the radio frequency signal RF2 to the coupler 20.

A power supply Vcc is coupled to the output side of the carrier amplifier 12 via an inductor L12. A capacitor C12 is provided between the carrier amplifier 12 and the carrier amplifier 13. The capacitor C12 cuts off a DC component of the radio frequency signal RF2.

The power supply Vcc is coupled to the output side of the carrier amplifier 13 via an inductor L13. A capacitor C13 is provided between the carrier amplifier 13 and the coupler 20. The capacitor C13 cuts off a DC component of the radio frequency signal RF3.

The peak amplifier 16 outputs a radio frequency signal RF5 obtained by amplifying the radio frequency signal RF4 to the peak amplifier 17. The peak amplifier 17 outputs a radio frequency signal RF6 obtained by amplifying the radio frequency signal RF5 to the coupler 20.

The power supply Vcc is coupled to the output side of the peak amplifier 16 via an inductor L16. A capacitor C16 is provided between the peak amplifier 16 and the peak amplifier 17. The capacitor C16 cuts off a DC component of the radio frequency signal RF5.

The power supply Vcc is coupled to the output side of the peak amplifier 17 via an inductor L17. A capacitor C17 is provided between the peak amplifier 17 and the coupler 20. The capacitor C17 cuts off a DC component of the radio frequency signal RF6.

The coupler 20 couples the radio frequency signal RF3 and the radio frequency signal RF6. In the first embodiment, the coupler 20 is a phase shifter, but the present disclosure is not limited thereto. The coupler 20 delays the phase of the radio frequency signal RF3 by 90°. The coupler 20 makes a sum of the radio frequency signal RF3 whose phase is delayed by 90° and the radio frequency signal RF6, and outputs the sum as a radio frequency signal RFout.

The radio frequency signal RF5, outputted from the driver stage peak amplifier 16, is inputted to the detection circuit 31. The detection circuit 31 is a circuit to detect the radio frequency signal RF5 and to generate a detection current or a detection voltage in accordance with the radio frequency signal RF5. The detection current or the detection voltage in accordance with the radio frequency signal RF5 is a current or a voltage that changes in accordance with the strength of the radio frequency signal RF5, and is a current or a voltage that reflects an operating state of the driver stage peak amplifier 16. In other words, the detection current or the detection voltage is a current or a voltage in accordance with the operating state of the driver stage peak amplifier. The detection circuit 31 further generates a control signal to control the operating state of the peak amplifier 17 based on the generated detection current or detection voltage, and outputs the control signal to the peak amplifier 17. The detection circuit 31 corresponds to a “generation circuit” of the present disclosure.

The radio frequency signal RF3 is inputted to the drive level detection circuit 34. The drive level detection circuit 34 detects a drive level (operating level) of the carrier amplifier 13 based on the radio frequency signal RF3. The drive level detection circuit 34 generates a signal S1 indicating the drive level. The signal S1 is inputted to the control circuit 22. The signal S1 may be a signal (inverted signal) that changes complementarily to the drive level of the carrier amplifier 13.

The control circuit 22 outputs a signal S2 based on the signal S1. The signal S2 is a signal to set a bias point of the peak amplifier 16. The operation of the control circuit 22 will be described later.

The control circuit 22 may further output a control signal S4 (not illustrated) based on the signal S1. In the case above, the control signal S4 is used as a signal to control the peak amplifier 17 in an auxiliary manner, for example. Specifically, the control signal S4 controls the state of the peak amplifier 17 together with a control signal S3 outputted from the detection circuit 31, for example. With the use of the above configuration, efficiency of the peak amplifier 17 may further be increased.

### Configuration of Drive Level Detection Circuit

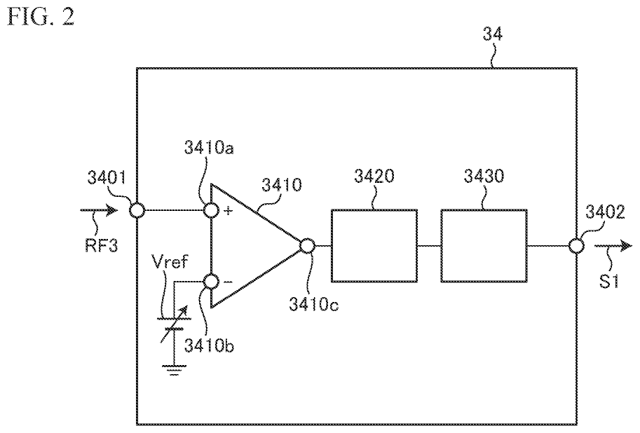

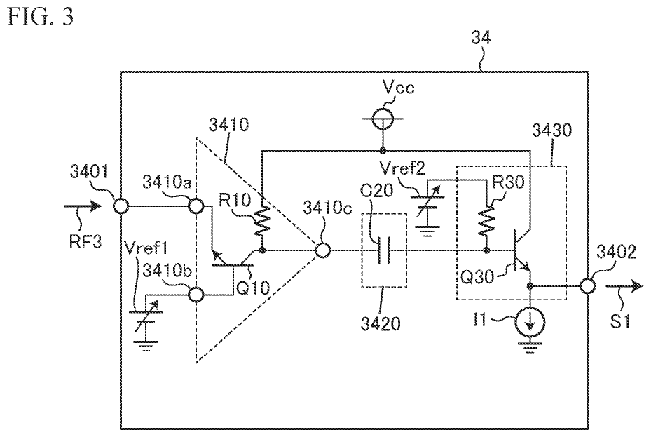

Next, the configuration of the drive level detection circuit 34 will be described in detail with reference to FIG. 2 and FIG. 3. FIG. 2 is a diagram illustrating an example of the configuration of the drive level detection circuit 34 in FIG. 1. FIG. 3 is a diagram illustrating a specific example of the configuration of the drive level detection circuit 34 in FIG. 1.

Referring to FIG. 2, the outline of configuration of the drive level detection circuit 34 will be described. As illustrated in FIG. 2, the drive level detection circuit 34 includes an input terminal 3401 electrically coupled to an output terminal of the carrier amplifier 13, and a detection terminal 3402 to detect the signal level of the output of the carrier amplifier 13.

The drive level detection circuit 34 includes, for example, the input terminal 3401, the detection terminal 3402, a comparison unit 3410, a DC removal unit 3420, and a detection unit 3430.

The input terminal 3401 is electrically coupled to the output terminal of the carrier amplifier 13, for example.

The detection terminal 3402 is electrically coupled to an input terminal of the control circuit 22, for example. That is, the detection terminal 3402 is a terminal to input the signal level of the output of the carrier amplifier 13 to the control circuit 22.

The comparison unit 3410 is, for example, a comparator using a voltage inputted to one input terminal as a reference voltage and outputs an output signal in accordance with a voltage inputted to another input terminal, with the reference voltage as a threshold.

Specifically, the comparison unit 3410 includes, for example, two input terminals 3410a and 3410b and an output terminal 3410c. One input terminal 3410a of the comparison unit 3410 is electrically coupled to the output terminal of the carrier amplifier 13, and the other input terminal 3410b of the comparison unit 3410 is electrically coupled to a reference voltage Vref. The output terminal 3410c of the comparison unit 3410 is electrically coupled to the DC removal unit 3420 described later.

The DC removal unit 3420 removes a DC component of the output signal outputted from the comparison unit 3410. That is, the DC removal unit 3420 causes the radio frequency component in the output signal to pass through.

For example, one terminal of the DC removal unit 3420 is electrically coupled to the output terminal 3410c of the comparison unit 3410, and the other terminal of the DC removal unit 3420 is electrically coupled to the detection unit 3430 described later.

The detection unit 3430 detects the output signal from which the DC component is removed through the DC removal unit 3420. Here, the detection unit 3430 converts the output signal into a DC component and outputs the DC component as the signal S1.

The input terminal of the detection unit 3430 is electrically coupled to the other terminal of the DC removal unit 3420. The output terminal of the detection unit 3430 is electrically coupled to the detection terminal 3402.

As described above, the drive level detection circuit 34 removes the DC component of the output signal outputted from the comparison unit 3410, and thus, can improve the response time delay of the comparison unit 3410 caused by the DC component. Further, the drive level detection circuit 34 removes the DC component of the output signal outputted from the comparison unit 3410, and thus, can suppress the fluctuation of a bias point of the detection unit 3430.

Meanwhile, in a saturation detection circuit in U.S. Patent Application Publication No. 2020/0028472, it takes a long time to stabilize a DC component of an output signal outputted from a comparator. In other words, in the saturation detection circuit, since the DC component outputted from the comparator affects the operation of the comparator itself, it takes a long time before the response stabilizes.

That is, the drive level detection circuit 34 has a configuration to remove the DC component of the output signal of the comparison unit 3410, thus prevents the output signal from affecting the operation of the comparison unit 3410. As a result, the drive level detection circuit 34 has a marked effect of improving the response time delay of the comparison unit 3410, as compared with the related art.

Next, an example of a specific configuration of the drive level detection circuit 34 will be described with reference to FIG. 3.

The comparison unit 3410 includes, for example, a transistor Q10 as illustrated in FIG. 3. An emitter of the transistor Q10 is electrically coupled to the output terminal (collector, for example) of the carrier amplifier 13. A base of the transistor Q10 is electrically coupled to a reference voltage Vref1. A collector of the transistor Q10 is electrically coupled to one terminal of the DC removal unit 3420. The collector of the transistor Q10 is electrically coupled to the power supply Vcc via a resistor R10.

The DC removal unit 3420 removes a DC component outputted from the comparison unit 3410. The DC component requires time to stabilize due to the influence of the operation of the comparison unit 3410 (operation of transistor Q10). The DC removal unit 3420, then, outputs a radio frequency component used as a detection signal to the detection unit 3430. That is, the DC removal unit 3420 isolates the comparison unit 3410 and the detection unit 3430 in a DC level so that the DC component which requires time to stabilize does not affect the detection unit 3430. As described above, the drive level detection circuit 34 removes the DC component which requires time to stabilize, and uses the radio frequency component as the detection signal. As a result, the response delay, which occurs when the DC component outputted from the comparison unit 3410 is used as the detection signal, may be eliminated.

The DC removal unit 3420 includes, for example, a capacitor C20. One terminal of the capacitor C20 is electrically coupled to the collector of the transistor Q10, and the other terminal of the capacitor C20 is electrically coupled to the detection unit 3430.

The detection unit 3430 is configured to include, for example, a transistor Q30. The transistor Q30 is, for example, an emitter-follower. The transistor Q30 has a conduction angle adjusted by a reference voltage Vref2, and smoothes, by using a capacitor (not illustrated), the radio frequency component of the signal outputted from the DC removal unit 3420 into a DC signal.

The base of the transistor Q30 is electrically coupled to the other terminal of the capacitor C20 of the DC removal unit 3420. The collector of the transistor Q30 is electrically coupled to the power supply Vcc. The emitter of the transistor Q30 is electrically coupled to the detection terminal 3402. Further, the base of the transistor Q30 is electrically coupled to the reference voltage Vref2 via a resistor R30. The emitter of the transistor Q30 is electrically coupled to a constant current source I1.

Next, the operation outline of the drive level detection circuit 34 will be described.

The collector of the common-emitter carrier amplifier 13 is electrically coupled to the drive level detection circuit 34. In the case above, an instantaneous minimum voltage of the collector of the carrier amplifier 13 becomes smaller (approaches 0 V) as the carrier amplifier 13 approaches saturation. That is, the drive level detection circuit 34 is in a conductive state during a period in which the voltage (signal level) of the radio frequency signal RF3, inputted to the input terminal 3401, is smaller than the reference voltage Vref1.

Here, a period of the conductive state represented by a range of an angle is referred to as a conduction angle, and the conduction angle increases as the radio frequency signal RF3 becomes larger. As the conduction angle increases, the DC component of the output signal outputted from the comparison unit 3410 also increases. In the drive level detection circuit 34, the DC component is removed by the DC removal unit 3420.

The drive level detection circuit 34 uses the detection unit 3430 of the emitter-follower. As a result, the detection unit 3430 has high input impedance, and thus an input current may be small. Since the input impedance of the detection unit 3430 is high, the radio frequency signal RF3 acts as a signal to operate the emitter-follower, but does not directly act on the DC component of the signal S1. That is, in the drive level detection circuit 34, by making the detection unit 3430 the emitter-follower (increasing AC input impedance), the interaction in AC level between the comparison unit 3410 and the detection unit 3430 may be suppressed.

This indicates that even when AC output impedance of the comparison unit 3410 is high, the interaction in AC level with the detection unit 3430 may be suppressed. For example, in a case that the AC output impedance of the comparison unit 3410 is high and the AC input impedance of the detection unit 3430 is low, when the detection unit 3430 starts to operate, the input impedance of the comparison unit 3410 normally lowers. That is, the AC output of the comparison unit 3410 normally becomes unstable. However, in the drive level detection circuit 34, by making the input impedance of the detection unit 3430 high with the use of the emitter-follower, the AC output of the comparison unit 3410 is stabilized.

In FIG. 3, the comparison unit 3410 is constituted of a common-base transistor, but the configuration is not limited thereto. For example, the comparison unit 3410 may be constituted of a common-emitter transistor. That is, the comparison unit 3410 may be a comparator that compares the collector voltage and the base voltage of the transistor.

Specifically, the comparison unit 3410 achieves the function of a comparator by using a phenomenon in which a base current increases when the potential of the collector becomes lower than the potential of the base by a base-emitter voltage Vbe or more. That is, the comparison unit 3410 may be configured to bias the base of the transistor to the base-emitter voltage Vbe and to cause the base current to flow when the potential of the collector approaches “0”.

In the case above, the emitter of the transistor of the comparison unit 3410 is electrically coupled to a ground. The collector of the comparison unit 3410 is electrically coupled to the collector (output terminal) of the carrier amplifier 13. The base of the comparison unit 3410 is electrically coupled to the reference voltage Vref1 and one terminal of the DC removal unit 3420.

As described above, by using a common-emitter transistor in the comparison unit 3410, transistor failure may be reduced as compared with a case of using a common-base transistor. This is because a large voltage is not applied between a base and an emitter when a common-emitter transistor is used, whereas a large voltage is applied between a base and an emitter when a common-base transistor is used.

### Operation of Control Circuit

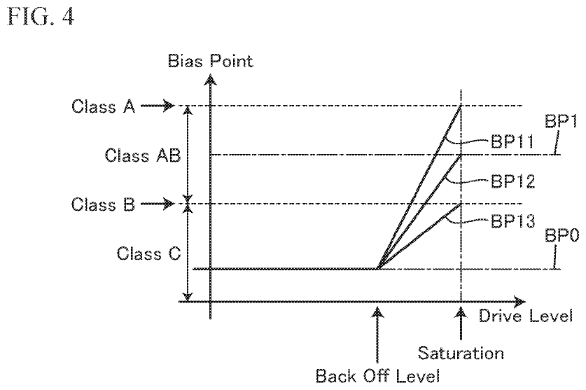

FIG. 4 is a diagram for describing the operation of the control circuit 22 in FIG. 1. In FIG. 4, a horizontal axis represents a drive level, and a vertical axis represents a bias point. Bias points of class A and class B are each indicated by a dashed line. Class between class A and class B is class AB, and class lower than class B is class C. It is a design matter to which level the bias point of a carrier amplifier, indicated by a dashed-and-dotted line BP1 in FIG. 4, is set. Further, it is a design matter to which of BP11, BP12, and BP13, indicated by solid lines, the bias point of a peak amplifier is set. A dashed-and-dotted line BP0 in FIG. 4 indicates a bias point of the peak amplifier when no signal is inputted. The control circuit 22 controls the bias point so that the driver stage peak amplifier 16 becomes class AB at a saturation point.

The control circuit 22 controls the bias point of the peak amplifier 16 based on the signal S1. The control circuit 22 outputs the signal S2 to set the bias of the peak amplifier 16.

The peak amplifier 16 performs an amplification operation when the input radio frequency signal RF4 is large. As illustrated in FIG. 4, when the peak amplifier 16 performs the class C operation while the radio frequency signal RF4 is not inputted, the drive level detection circuit 34 detects the saturation point at a drive level higher than a certain back off level. The control circuit 22, then, controls the bias point of the peak amplifier 16 so that the peak amplifier 16 performs the amplification operation even when the input is small. That is, when the drive level detection circuit 34 detects the saturation point, the control circuit 22 controls the bias point of the peak amplifier 16 so that the peak amplifier 16 performs the amplification operation even when the input is small.

That is, the control circuit 22 has a function as an interface circuit that inputs the drive level of the power stage carrier amplifier 13 to the driver stage peak amplifier 16. The control circuit 22 may input the drive level signal to the peak amplifier 16 as it is, or may invert the drive level signal and input the inverted drive level signal to the peak amplifier 16.

The control circuit 22 sets a bias point lower than the bias point of the carrier amplifier 12 to the driver stage peak amplifier 16 when the input signal is not present or low. At this time, the comparison in height of the bias point of the carrier amplifier 12 and the bias point set to the driver stage peak amplifier 16 is performed using values obtained as follows, for example. The values are each obtained by normalizing the collector (or drain) current, when the input signal is not present or low, of the transistor constituting each of the carrier amplifier 12 and the driver stage peak amplifier 16, with an emitter area (or gate width) of the transistor. The control circuit 22 raises the bias point of the driver stage peak amplifier 16 in a drive level higher than a certain back off level. Further, the control circuit 22 sets the bias point in the saturation state of the driver stage peak amplifier 16 to a bias point higher than that when the input signal is not present or low. The control circuit 22 sets the bias point so that the driver stage peak amplifier 16 operates in class AB.

### Peak Amplifier

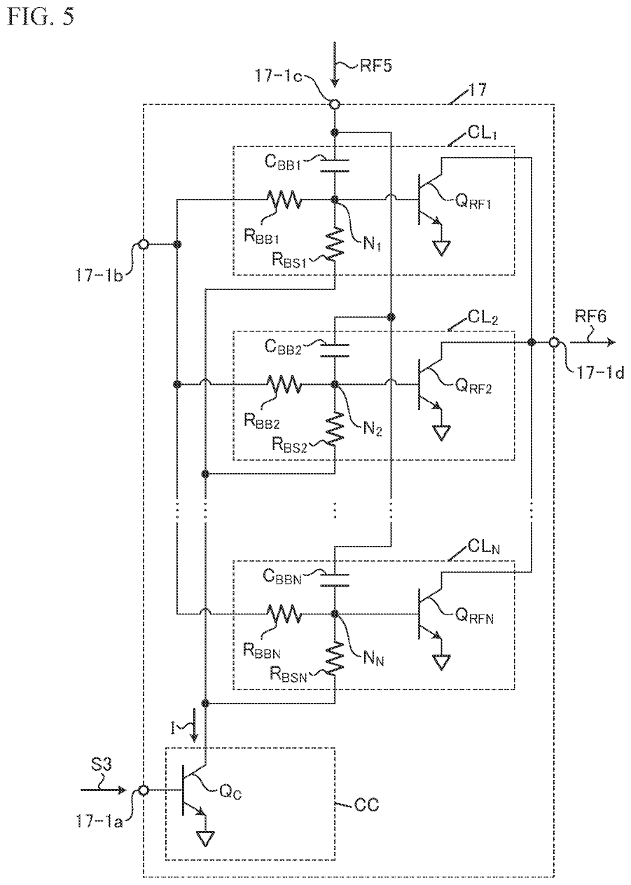

FIG. 5 is a diagram illustrating a configuration of the peak amplifier 17 included in the Doherty amplifier 1 in FIG. 1. In FIG. 5, each transistor is a bipolar transistor, but the present disclosure is not limited thereto. The bipolar transistor is exemplified by a heterojunction bipolar transistor (HBT), but the present disclosure is not limited thereto. The transistor may be, for example, a field effect transistor (FET). The transistor may be a multi-finger transistor in which a plurality of unit transistors are electrically coupled in parallel. The unit transistor is a minimum structure to constitute a transistor.

When each transistor is an FET, a source corresponds to an emitter of the bipolar transistor, a gate corresponds to a base of the bipolar transistor, and a drain corresponds to a collector of the bipolar transistor.

The peak amplifier 17 has an enable terminal 17-1a. The control signal S3 is inputted to the enable terminal 17-1a from the detection circuit 31 (see FIG. 1). A bias signal outputted from a bias circuit 19 is inputted to a terminal 17-1b of the peak amplifier 17. The radio frequency signal RF5 is inputted to a terminal 17-1c of the peak amplifier 17. The radio frequency signal RF6 is outputted from a terminal 17-1d of the peak amplifier 17 to the coupler 20 (see FIG. 1).

The peak amplifier 17 includes cells CL₁, CL₂, . . . , CL_{N}. That is, the peak amplifier 17 is configured by a multi-finger (multi-cell) transistor including a plurality of cells. However, the present disclosure is not limited thereto. The peak amplifier 17 may be configured by a single finger (single cell) transistor including one cell.

The peak amplifier 17 further includes a state control circuit CC that controls the cells CL₁, CL₂, . . . , CL_{N} in an operating state (radio frequency signal amplification state) or a non-operating state (radio frequency signal non-amplification state). The state control circuit CC includes a transistor Q_{c}.

The cell CL₁ includes a transistor Q_{RF1}, a capacitor C_{BB1}, resistors R_{BB1} and R_{BS1}. The transistor Q_{RF1} is exemplified by a unit transistor, but the present disclosure is not limited thereto.

One end of the resistor R_{BB1} is electrically coupled to the terminal 17-1b. The terminal 17-1b is coupled to the bias circuit 19 to supply a bias to the peak amplifier 17. The resistor R_{BB1} is coupled to a transistor of the bias circuit 19 at the output stage to the peak amplifier 17. For example, the resistor R_{BB1} is emitter-follower-coupled to the transistor in the bias circuit 19. The other end of the resistor R_{BB1} is electrically coupled to a node N₁. One end of the capacitor C_{BB1} is electrically coupled to the terminal 17-1c. The other end of the capacitor C_{BB1} is electrically coupled to the node N₁. The base of the transistor Q_{RF1} is electrically coupled to the node N₁. The emitter of the transistor QRF is electrically coupled to the reference potential. The collector of the transistor Q_{RF1} is electrically coupled to the terminal 17-1d.

A bias current or a bias voltage is inputted to the base of the transistor Q_{RF1} via the resistor R_{BB1}. The radio frequency signal RF5 is inputted to the base of the transistor Q_{RF1} via the capacitor C_{BB1}. The transistor Q_{RF1} amplifies the radio frequency signal RF5 and outputs the radio frequency signal RF6 from the collector to the terminal 17-1d.

One end of the resistor R_{BS1} is electrically coupled to the node N₁. The other end of the resistor R_{BS1} is electrically coupled to the collector of the transistor Q_{c}.

The cell CL₂ includes a transistor Q_{RF2}, a capacitor C_{BB2}, resistors R_{BB2} and R_{BS2}. The transistor Q_{RF2} is exemplified by a unit transistor, but the present disclosure is not limited thereto. The coupling relationship among the transistor Q_{RF2}, the capacitor C_{BB2}, a node N₂, and the resistors R_{BB2} and R_{BS2} is the same as the coupling relationship among the transistor Q_{RF1}, the capacitor C_{BB1}, the node N₁, and the resistors R_{BB1} and R_{BS1}, and thus the description thereof will be omitted.

The cell CL_{N} includes a transistor Q_{RFN}, a capacitor C_{BBN}, and resistors R_{BBN} and R_{BSN}. The transistor Q_{RFN} is exemplified by a unit transistor, but the present disclosure is not limited thereto. The coupling relationship among the transistor Q_{RFN}, the capacitor C_{BBN}, the node N_{N}, and the resistors R_{BBN} and R_{BSN} is the same as the coupling relationship among the transistor Q_{RF1}, the capacitor C_{BB1}, the node N₁, and the resistors R_{BB1} and R_{BS1}, and thus the description thereof will be omitted.

The collector of the transistor Q_{c} is electrically coupled to the other end of the resistor R_{BS1}, the other end of the resistor R_{BS2}, . . . and the other end of the resistor R_{BSN}. The base of the transistor Q_{c} is electrically coupled to the enable terminal 17-1a. The control signal S3 is inputted to the base of the transistor Q_{c}. The emitter of the transistor Q_{c} is electrically coupled to the reference potential.

The operation of the state control circuit CC will be described.

When the control signal S3 is at a high level, the transistor Q_{c} turns on, and a current I flows from the node N₁, the node N₂, . . . , the node N_{N} to the collector of the transistor Q_{c} via the resistor R_{BS1}, the resistor R_{BS2}, . . . , the resistor R_{BSN}, respectively. That is, the transistor Q_{c} draws the current I from the node N₁, the node N₂, . . . , and the node N_{N}.

When the current is drawn from the node N₁, a voltage drop occurs in the resistor R_{BS1} through which the drawn current flows, and the voltage of the node N₁ lowers. Therefore, the transistor Q_{RF1} is lowered in the base voltage, and becomes unable to amplify the radio frequency signal RF5.

Similarly, when the current is drawn from the node N₂, a voltage drop occurs in the resistor R_{BS2} through which the drawn current flows, and the voltage of the node N₂ lowers. Therefore, the transistor Q_{RF2} is lowered in the base voltage, and becomes unable to amplify the radio frequency signal RF5.

Similarly, when the current is drawn from the node N_{N}, a voltage drop occurs in the resistor R_{BSN} through which the drawn current flows, and the voltage of the node N_{N} lowers. Therefore, the transistor Q_{RFN} is lowered in the base voltage, and becomes unable to amplify the radio frequency signal RF5.

That is, when the control signal S3 becomes a high level, the peak amplifier 17 becomes a non-operating state (radio frequency signal non-amplification state).

When the control signal S3 is at a low level, the transistor Q_{c} turns off, and the current I does not flow from the node N₁, the node N₂, . . . , and the node N_{N} to the collector of the transistor Q_{c}. That is, the transistor Q_{c} does not draw the current I from the node N₁, the node N₂, . . . , and the node N_{N}.

Therefore, the transistor Q_{RF1} can amplify the radio frequency signal RF5 because the base voltage does not lower. Similarly, the transistor Q_{RF2} can amplify the radio frequency signal RF5 because the base voltage does not lower. Similarly, the transistor Q_{RFN} can amplify the radio frequency signal RF5 because the base voltage does not lower.

That is, when the control signal S3 becomes a low level, the peak amplifier 17 becomes an operating state (radio frequency signal amplification state).

The position of the state control circuit CC may be separated from the positions of the cells CL₁, CL₂, . . . , CL_{N}. This is because the current I is less likely to be influenced by temperature difference. Normally, the detection circuit 31, which is a generation unit of the control signal S3, is disposed separated from the peak amplifier 17, which is the final stage amplifier. Therefore, temperature difference often occurs between the detection circuit 31 and the peak amplifier 17, which tends to be heated to high temperature because of the requirement of high output power. As a result, the threshold voltage of the transistor disposed near the peak amplifier 17 tends to be lower than the threshold voltage of the transistor disposed near the detection circuit 31. Here, when the state control circuit CC is disposed near the peak amplifier 17, the threshold voltage of the transistor Q_{c} included in the state control circuit CC lowers due to the temperature rise near the peak amplifier 17. That is, in a case that the state control circuit CC is disposed near the position of the cells CL₁, CL₂, . . . , CL_{N}, even when the control signal S3 generated by the detection circuit 31 is at a low level, the state control circuit CC may erroneously recognize that “the control signal S3 is at a high level”. In contrast, when the state control circuit CC is disposed separated from the cells CL₁, CL₂, . . . , CL_{N}, the decrease in the threshold voltage of the transistor Q_{c} included in the state control circuit CC can be suppressed. Therefore, it becomes easy to prevent the state control circuit CC from erroneously recognizing the control signal S3. For example, the state control circuit CC may be disposed in the control circuit 22 (see FIG. 1). In the case above, it can be considered that the current I corresponds to the control signal S3.

Meanwhile, the position of the resistor R_{BB1} and the position of the transistor Q_{RF1} can be close to each other. This is because a voltage is easily influenced by parasitic capacitance. When the resistor RBI and the transistor Q_{RF1} are disposed separated from each other, the transfer speed of the voltage drop generated in the resistor R_{BB1} to the base of the transistor Q_{RF1} becomes slow due to the influence of the parasitic capacitance. That is, the switching speed between the operating state and the non-operating state of the transistor Q_{RF1} becomes slow. Therefore, in order to make the switching between the states of the transistor Q_{RF1} fast, the position of the resistor R_{BB1} and the position of the transistor Q_{RF1} can be close to each other. The same applies to other cells.

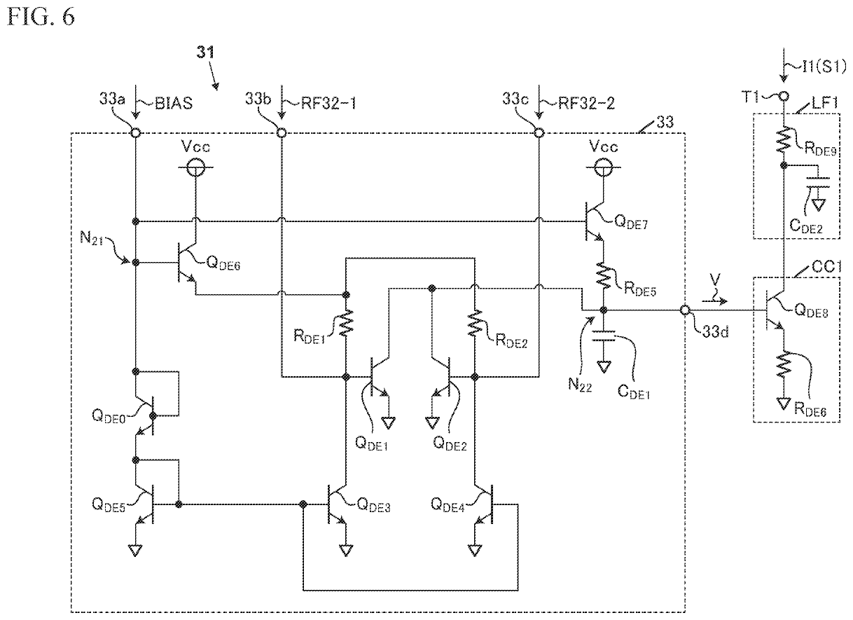

FIG. 6 is a diagram illustrating a configuration example of the detection circuit 31.

A bias current BIAS is inputted to a terminal 33a of the detection circuit 31. A first phase radio frequency signal RF32-1 is inputted to a terminal 33b of a control circuit 33. A second phase radio frequency signal RF32-2 is inputted to a terminal 33c of the control circuit 33. A voltage V is outputted from a terminal 33d of the control circuit 33. The detection circuit 31 will be described here in a case that the peak amplifier 16 is a differential-power amplifier, that is, in a case that the peak amplifier 16 outputs the first phase radio frequency signal RF32-1 and the second phase radio frequency signal RF32-2 that is different from the first phase radio frequency signal RF32-1 in phase by approximately 180°. When the peak amplifier 16 is a single-ended power amplifier, the peak amplifier 16 is changed to a single-ended amplifier (not illustrated) excluding transistors Q_{DE2}, Q_{DE4}, a resistor R_{DE2}, and the terminal 33c from the differential-amplifier including transistors Q_{DE1} to Q_{DE4} and resistors R_{DE1} and R_{DE2}.

The detection circuit 31 includes transistors Q_{DE0} to Q_{DE7}, resistors R_{DE1}, R_{DE2}, and R_{DE5}, and a capacitor C_{DE1}.

The transistors Q_{DE1} and Q_{DE2} constitute a differential pair. Transistors Q_{DE0} and Q_{DE3} to Q_{DE6} and resistors R_{DE1} and R_{DE2} give a bias to the differential pair.

The collector and base of the transistor Q_{DE0} are electrically coupled to the terminal 33a via a node N₂₁. That is, the transistor Q_{DE0} is diode-coupled. The emitter of the transistor Q_{DE0} is electrically coupled to the collector and base of the transistor Q_{DE5}. That is, the transistor Q_{DE5} is diode-coupled. The emitter of the transistor Q_{DE5} is electrically coupled to the reference potential.

A current is inputted from the node N₂₁ to the collector of the transistor Q_{DE0}. The transistor Q_{DE0} and the transistor Q_{DE5} each generates a constant voltage. The voltage above is the voltage of the node N₂₁. The voltage of the node N₂₁ is inputted to the base of the transistor Q_{DE6} and the base of the transistor Q_{DE7}.

The collector of the transistor Q_{DE6} is electrically coupled to a power supply voltage Vcc. The base of the transistor Q_{DE6} is electrically coupled to the node N₂₁. The emitter of the transistor Q_{DE6} is electrically coupled to one end of the resistor R_{DE1} and one end of the resistor R_{DE2}. The transistor Q_{DE6} outputs a current in accordance with the voltage of the node N₂₁ to one end of the resistor R_{DE1} and one end of the resistor R_{DE2}.

The other end of the resistor R_{DE1} is electrically coupled to the base of the transistor Q_{DE1}. The other end of the resistor R_{DE2} is electrically coupled to the base of the transistor Q_{DE2}.

The base of the transistor Q_{DE1} is electrically coupled to the terminal 33b, and the first phase radio frequency signal RF32-1 is inputted to the base of the transistor Q_{DE1}. The emitter of the transistor Q_{DE1} is electrically coupled to the reference potential. The collector of the transistor Q_{DE1} is electrically coupled to a node N₂₂.

The base of the transistor Q_{DE2} is electrically coupled to the terminal 33c, and the second phase radio frequency signal RF32-2 is inputted to the base of the transistor Q_{DE2}. The emitter of the transistor Q_{DE2} is electrically coupled to the reference potential. The collector of the transistor Q_{DE2} is electrically coupled to the node N₂₂.

The collector of the transistor Q_{DE3} is electrically coupled to the other end of the resistor R_{DE1} and the base of the transistor Q_{DE1}. The emitter of the transistor Q_{DE3} is electrically coupled to the reference potential. The base of the transistor Q_{DE3} is electrically coupled to the base and the collector of the transistor Q_{DE5}. That is, the transistor Q_{DE3} and the transistor Q_{DE5} are coupled in a current mirror configuration.

The transistor Q_{DE6}, the resistor R_{DE1}, and the transistor Q_{DE3} are set to have such device values that the transistor Q_{DE1} turns off when the first phase radio frequency signal RF32-1 is not present, and the transistor Q_{DE1} operates when the first phase radio frequency signal RF32-1 becomes present.

The collector of the transistor Q_{DE4} is electrically coupled to the other end of the resistor R_{DE2} and the base of the transistor Q_{DE2}. The emitter of the transistor Q_{DE4} is electrically coupled to the reference potential. The base of the transistor Q_{DE4} is electrically coupled to the base and the collector of the transistor Q_{DE5}. That is, the transistor Q_{DE4} and the transistor Q_{DE5} are coupled in a current mirror configuration.

The transistor Q_{DE6}, the resistor R_{DE2}, and the transistor Q_{DE4} are set to have such device values that the transistor Q_{DE2} turns off when the second phase radio frequency signal RF32-2 is not present, and the transistor Q_{DE2} operates when the second phase radio frequency signal RF32-2 becomes present.

The collector of the transistor Q_{DE7} is electrically coupled to the power supply voltage Vcc. The base of the transistor Q_{DE7} is electrically coupled to the node N₂₁. The emitter of the transistor Q_{DE7} is electrically coupled to the node N₂₂.

One end of the capacitor C_{DE1} is electrically coupled to the node N₂₂. The other end of the capacitor C_{DE1} is electrically coupled to the reference potential. The capacitor C_{DE1} is a low pass filter to stabilize the voltage of the node N₂₂. The voltage of the node N₂₂ is the voltage V.

The operation of the control circuit 33 will be described.

When the first phase radio frequency signal RF32-1 and the second phase radio frequency signal RF32-2 are each not present, the transistors Q_{DE1} and Q_{DE2} are each off, and thus the collector current of each of the transistors Q_{DE1} and Q_{DE2} does not flow. Therefore, the voltage drop in the resistor R_{DE5} does not occur, and the voltage V becomes a voltage close to that of the emitter of the transistor Q_{DE7}. Since the transistor Q_{DE7} operates as an emitter-follower, the voltage above has a level enough to turn on the transistor Q_{DE8}.

When the first phase radio frequency signal RF32-1 and the second phase radio frequency signal RF32-2 are each present, the collector current of each of the transistors Q_{DE1} and Q_{DE2} flows, and a voltage drop occurs at the other end of the resistor R_{DE5}, that is, at the node N₂₂. Therefore, the voltage V lowers.

As the first phase radio frequency signal RF32-1 and the second phase radio frequency signal RF32-2 each become larger, the collector current of each of the transistors Q_{DE1} and Q_{DE2} increases, the voltage drop generated at the other end of the resistor R_{DE5}, that is, the voltage drop occurred at the node N₂₂ becomes larger, and the voltage V greatly lowers.

That is, the control circuit 33 makes the voltage V be the highest when the first phase radio frequency signal RF32-1 and the second phase radio frequency signal RF32-2 are each not present, and makes the voltage V be low in accordance with the first phase radio frequency signal RF32-1 and the second phase radio frequency signal RF32-2. The voltage V is inputted to the state control circuit CC1.

The state control circuit CC1 includes a transistor Q_{DE8} and a resistor R_{DE6}. The base of the transistor Q_{DE8} is electrically coupled to the terminal 33d, and the voltage V is inputted to the base of the transistor Q_{DE8}. The collector of the transistor Q_{DE8} is electrically coupled to a low pass filter LF1. The emitter of the transistor Q_{DE5} is electrically coupled to one end of the resistor R_{DE6}. The other end of the resistor R_{DE6} is electrically coupled to the reference potential.

The low pass filter LF1 includes a resistor R_{DE9} and a capacitor C_{DE2}. One end of the resistor R_{DE9} is electrically coupled to the collector of the transistor Q_{DE8}. The other end of the resistor R_{DE9} is electrically coupled to a terminal T1. The terminal T1 is electrically coupled to the cells in the peak amplifier 17 (see FIG. 1) in the next stage.

When the voltage V is high, that is, when the first phase radio frequency signal RF32-1 and the second phase radio frequency signal RF32-2 are each not present, the state control circuit CC draws the current I1 from the cells in the peak amplifier 17 of the next stage. As a result, the peak amplifier 17 in the next stage is brought into a non-operating state.

When the voltage V is low, that is, when the first phase radio frequency signal RF32-1 and the second phase radio frequency signal RF32-2 are each present, the state control circuit CC does not draw the current I1 from the cells in the peak amplifier 17 of the next stage. As a result, the peak amplifier 17 of the next stage becomes the operating state.

### Effect

For example, as in the technique described in U.S. Patent Application Publication No. 2016/0241209, when a bias circuit 19 controls the operating state (radio frequency signal amplification state) and the non-operating state (radio frequency signal non-amplification state) of the peak amplifier 17 by changing the bias current or the bias voltage, the switching speed becomes slow. This is because it takes time to change a DC current (bias current) or a DC voltage (bias voltage).

Meanwhile, the peak amplifier 17 can be controlled to the operating state or to the non-operating state by receiving the control signal S3 of a high level or a low level to the enable terminal 17-1a. The peak amplifier 17 is controlled to the operating state or to the non-operating state by the control signal S3. The control signal S3 can control the peak amplifier 17 to the operating state or to the non-operating state. Thus, the bias circuit 28 does not need to change the bias current or the bias voltage.

As a result, the peak amplifier 17 can switch fast between the operating state and the non-operating state.

Further, with the state control circuit CC drawing the current I from the nodes N₁, N₂, . . . , N_{N}, the peak amplifier 17 can be controlled to the operating state or to the non-operating state.

As described above, the peak amplifier 17 can be controlled to the operating state or to the non-operating state by drawing the current I. This makes it possible to make the switching fast as compared with the control of the operating state and the non-operating state by a voltage.

With the configuration above, deterioration in quality of a radio frequency output signal in the Doherty amplifier can be suppressed. Further, the control circuit 22 is controlled by the signal S1 based on the drive level of the power stage carrier amplifier 13. The drive level of the power stage carrier amplifier 13 is a signal that changes in accordance with the bias of the carrier amplifier 13. The control circuit 22 inputs, to the driver stage peak amplifier 16, a bias based on the signal S1 based on the drive level of the power stage carrier amplifier 13. Further, the output signal of the driver stage peak amplifier 16 is outputted to the detection circuit 31, and the output signal of the detection circuit 31 is outputted to the terminal 17-1a of the power stage peak amplifier 17, whereby the bias point of the power stage peak amplifier 17 is controlled. In other words, the control signal to control the bias point of the power stage peak amplifier 17 is generated based on the output signal of the driver stage peak amplifier 16. Therefore, it is optional to separately provide a control signal generation circuit to generate a control signal to control the bias point of the power stage peak amplifier 17. As a result, the circuit size of the Doherty amplifier 1 can be reduced.

### Second Embodiment

### Overall Configuration

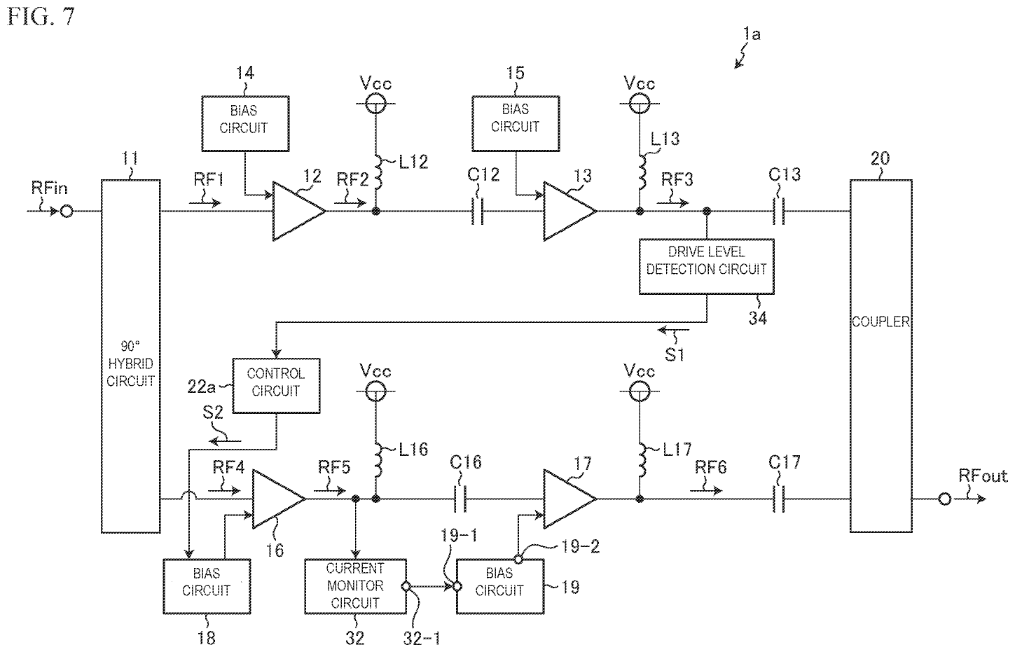

FIG. 7 is a diagram illustrating a configuration of a Doherty amplifier according to a second embodiment. In FIG. 7, a Doherty amplifier 1a of the second embodiment includes a current monitor circuit 32 instead of the detection circuit 31 in the configuration of the Doherty amplifier 1 described with reference to FIG. 1.

The current monitor circuit 32 detects the current of the driver stage peak amplifier 16. Specifically, the current monitor circuit 32 detects a supply current supplied from the power supply to the driver stage peak amplifier 16. The current monitor circuit 32 generates a monitor current in accordance with the supply current. The monitor current in accordance with the supply current is a current or a voltage that changes in accordance with the strength of the radio frequency signal RF4 inputted to the driver stage peak amplifier 16, and is a current that reflects the operating state of the driver stage peak amplifier 16. In other words, the monitor current is a current in accordance with the operating state of the driver stage peak amplifier 16. The current monitor circuit 32 outputs the detected current of the peak amplifier 16 to the bias circuit 19. The current monitor circuit 32 corresponds to a “generation circuit” of the present disclosure. The bias circuit 19 sets a bias of the power stage peak amplifier 17.

The Doherty amplifier 1a of the second embodiment includes a control circuit 22a instead of the control circuit 22 in the configuration of the Doherty amplifier 1 described with reference to FIG. 1. The control circuit 22a outputs a signal S2 based on a signal S1. The signal S2 is a signal to set the bias of the peak amplifier 16. Current Monitor Circuit, Bias Circuit, and the like

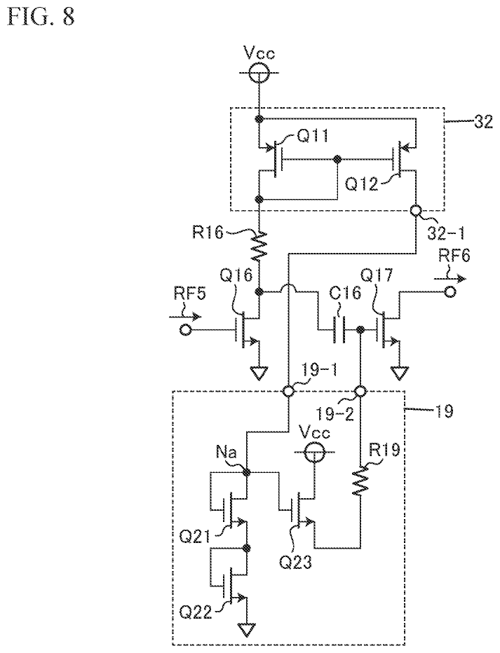

FIG. 8 is a diagram illustrating an example of the configuration of the current monitor circuit 32, the bias circuit 19, and the like in FIG. 7. In the present example, the driver stage peak amplifier 16 is illustrated as one transistor Q16. The power stage peak amplifier 17 is illustrated as one transistor Q17.

The radio frequency signal RF5 is inputted to the gate of the transistor Q16. A capacitor C16 is coupled in series between the drain of the transistor Q16 and the gate of the transistor Q17. The radio frequency signal RF6 is outputted from the drain of the transistor Q17. The source of the transistor Q16 and the source of the transistor Q17 are electrically coupled to the reference potential.

The current monitor circuit 32 has a terminal 32-1. The bias circuit 19 has terminals 19-1 and 19-2. The terminal 32-1 of the current monitor circuit 32 is electrically coupled to the terminal 19-1 of the bias circuit 19. The terminal 19-2 of the bias circuit 19 is electrically coupled to the gate of the transistor Q17.

The current monitor circuit 32 includes transistors Q11 and Q12 constituting a current mirror circuit. The transistors Q11 and Q12 are each P-channel metal oxide semiconductor field effect transistor (MOSFET). The sources of the transistors Q11 and Q12 are each electrically coupled to the power supply Vcc. The source of the transistor Q11 and the source of the transistor Q12 are electrically coupled to each other. The gate of the transistor Q11 and the gate of the transistor Q12 are electrically coupled to each other. The gate of the transistor Q11 and the drain of the transistor Q11 are electrically coupled to each other. The drain of the transistor Q12 is electrically coupled to the terminal 32-1 of the current monitor circuit 32.

A resistor R16 is electrically coupled between the drain of the transistor Q11 and the drain of the transistor Q16 of the current monitor circuit 32. The resistor R16 is a load resistor to detect a current.

The bias circuit 19 includes transistors Q21, Q22, and Q23, and a resistor R19. The transistors Q21, Q22, and Q23 are each N-channel MOSFET. The transistors Q21 and Q22 are each diode-coupled between the terminal 19-1 and the reference potential. The gate of the transistor Q23 is electrically coupled to the terminal 19-1. The drain of the transistor Q23 is electrically coupled to the power supply Vcc. The source of the transistor Q23 is electrically coupled to the terminal 19-2 via the resistor R19. The current monitor circuit 32 and the bias circuit 19 illustrated in FIG. 7 are each constituted by an FET, but may be constituted by a bipolar transistor.

Next, the operation will be described. The current mirror circuit formed by the transistors Q11 and Q12 outputs a current obtained by duplicating a current flowing through the transistor Q16 corresponding to the peak amplifier 16. The bias circuit 19 sets the bias of the peak amplifier 17 based on the current duplicated by the current mirror circuit.

When the radio frequency signal RF5 is inputted to the gate of the transistor Q16, the transistor Q16 turns on. When the transistor Q16 turns on and the current flowing through the resistor R16 increases, the current detected by the current monitor circuit 32 increases. As a result, the current flowing from the terminal 32-1 of the current monitor circuit 32 into the terminal 19-1 of the bias circuit 19 increases. When the current flowing into the terminal 19-1 increases, the current flowing through the transistors Q21 and Q22 increases, and the voltage of a node Na becomes higher. As a result, a current is outputted from the source of the transistor Q23 through the resistor R19 and the terminal 19-2, and is applied to the gate of the transistor Q17 as a bias. The bias controls the operating state of the power stage peak amplifier 17 including the transistor Q17. The operating state includes, for example, switching between an amplification operating state and a non-amplification operating state, and a gain in the amplification operation state.

With the configuration above, deterioration in quality of a radio frequency output signal in the Doherty amplifier may be suppressed. Further, the control circuit 22a is controlled by the signal S1 based on the drive level of the power stage carrier amplifier 13. The drive level of the power stage carrier amplifier 13 is a signal that changes in accordance with the bias of the carrier amplifier 13. The control circuit 22a inputs, to the driver stage peak amplifier 16, a bias based on the signal S1 based on the drive level of the power stage carrier amplifier 13. Further, the output signal of the driver stage peak amplifier 16 is outputted to the current monitor circuit 32, and the output signal of the current monitor circuit 32 is outputted to the bias circuit 19, whereby the bias point of the power stage peak amplifier 17 is controlled. In other words, the control signal to control the bias point of the power stage peak amplifier 17 is generated based on the output signal of the driver stage peak amplifier 16. Therefore, it is optional to separately provide a control signal generation circuit to generate a control signal to control the bias point of the power stage peak amplifier 17. As a result, the circuit size of the Doherty amplifier 1a can be reduced.

What is claimed is:

1. A Doherty amplifier, comprising:
a carrier amplifier configured to amplify a radio frequency signal;
a peak amplifier configured to amplify the radio frequency signal, and comprising a driver stage peak amplifier and a power stage peak amplifier configured to receive an output of the driver stage peak amplifier;
a drive level detection circuit configured to detect a drive level of the carrier amplifier;
a control circuit configured to output a signal that sets a bias of the driver stage peak amplifier based on a drive level signal indicating the drive level detected by the drive level detection circuit; and
a generation circuit configured to generate a current or a voltage in accordance with an operating state of the driver stage peak amplifier,
wherein an operating state of the power stage peak amplifier is controlled based on the current or the voltage generated by the generation circuit in accordance with the operating state of the driver stage peak amplifier.

2. The Doherty amplifier according to claim 1, wherein the generation circuit comprises a detection circuit configured to:
generate a detection current or a detection voltage in accordance with a radio frequency signal outputted from the driver stage peak amplifier, and
output, to the power stage peak amplifier, a control signal that controls the operating state of the power stage peak amplifier based on the detection current or the detection voltage.

3. The Doherty amplifier according to claim 2, wherein the control circuit is configured to:
set a bias point of the driver stage peak amplifier to be lower than a bias point of the carrier amplifier when an input signal is not present or is low,
raise the bias point of the driver stage peak amplifier in a drive level to be higher than a back off level,
set the bias point of the driver stage peak amplifier in a saturation state to be higher than the bias point when the input signal is not present or low, and
set the bias point of the driver stage peak amplifier to operate the driver stage peak amplifier in class AB.

4. The Doherty amplifier according to claim 2, wherein the control circuit is further configured to output a control signal that controls a state of the power stage peak amplifier.

5. The Doherty amplifier according to claim 4, wherein the power stage peak amplifier is controlled to be in the operating state or in a non-operating state by the control signal.

6. The Doherty amplifier according to claim 1,
wherein the generation circuit comprises a current monitor circuit configured to generate a monitor current in accordance with a supply current to the driver stage peak amplifier,
wherein the generation circuit further comprises a bias circuit configured to set a bias of the power stage peak amplifier based on the monitor current, and
wherein the operating state of the power stage peak amplifier is controlled by the bias set by the bias circuit.

7. The Doherty amplifier according to claim 6,
wherein the current monitor circuit comprises a current mirror circuit configured to output a current obtained by duplicating a current of the driver stage peak amplifier, and
wherein the bias circuit is configured to set the bias of the power stage peak amplifier based on the current duplicated by the current mirror circuit.
